(19) United States
(12) Patent Application Publication
(10) Pub. No.: US 2015/0155837 A1
(43) Pub. Date: Jun. 4, 2015

(54) AMPLIFIER, TRANSMITTER, AND AMPLIFICATION METHOD

(71) Applicant: FUJITSU LIMITED, Kawasaki-shi (JP)

(72) Inventor: Alexander Nikolaevich LOZHKIN, Kawasaki (JP)

(21) Appl. No.: 14/532,169

(22) Filed: Nov. 4, 2014

(30) Foreign Application Priority Data
Dec. 3, 2013 (JP) 2013-250621

(51) Int. Cl. H03F 1/32; H03F 3/19; H03F 3/21

(52) U.S. Cl. CPC H03F 1/3247; H03F 3/21; H03F 3/19; H03F 2200/451; H03F 2201/3215

(57) ABSTRACT

An amplifier includes an increase unit, a generator, a decrease unit, an adder, and an amplification unit. The increase unit increases a rate of an input signal and samples the input signal. The generator generates a predistorter signal for compensating for distortion occurring due to amplification of the input signal, from the input signal whose rate is increased by the increase unit. The decrease unit configured to decrease a rate of the predistorter signal generated by the generator to the rate before being increased by the increase unit. The adder adds the predistorter signal whose rate is decreased by the decrease unit to the input signal before the rate is increased. The amplification unit configured to amplify the input signal to which the predistorter signal is added by the adder.

### CROSS-REFERENCE TO RELATED APPLICATION

This application is based upon and claims the benefit of priority of the prior Japanese Patent Application No. 2013-250621, filed on Dec. 3, 2013, the entire contents of which are incorporated herein by reference.

### FIELD

The embodiments discussed herein are related to an amplifier, a transmitter, and an amplification method.

### BACKGROUND

An increase in transmission output of a base station has been requested along with an increase in an amount of communication data over wireless communication. A high power amplifier (HPA) is used as a device that increases transmission output of a base station. A digital predistorter (DPD) is sometimes used for the HPA as a device that estimates and compensates for the distortion of a radio frequency (RF) signal in a nonlinear region.

FIG. 10 illustrates a diagram of how input signal spectrum is spread by HPA 100. As illustrated in

FIG. 10, the bandwidth of a Tx signal before being input to the HPA 100 is Tx BW. After the Tx signal is output from the HPA 100, the bandwidth Tx BW is spread to N-times bandwidth N*Tx BW (N=3, 5, . . . , 11) in a direction of frequency f. Spread areas E1 and E2 correspond to HPA output due to intermodulation distortions (IMDs), and a spread width is different depending on N non-linearity order of the HPA 100.

FIG. 11 illustrates a diagram of how the input signal is compensated by DPD 200. As illustrated in FIG. 11, the bandwidth of the Tx signal before being input to the DPD 200 is Tx BW. The DPD 200 spreads the input signal spectrum up to the bandwidth N*Tx BW as illustrated in FIG. 10 before the signal is amplified by the HPA 100, to thereby pre-compensate for the distortion occurring upon amplification. Thus a predistorter (PD) signal is obtained.

FIG. 12 illustrates a diagram of how aliases A1 and A2 arise in PD signal spectrums. As illustrated in FIG. 12, the PD signal after the predistortion is generated in a clock (cycle) the same as that of the Tx signal as a main signal. Meanwhile, as explained above, each PD signal spectrum is spread at least 3 times in the direction of frequency f. Therefore, the PD signal spectrums overlap each other between the adjacent PD signals, and the aliases A1 and A2 arise.

FIG. 13 illustrates a diagram of how the aliases are suppressed by oversampling. As illustrated in FIG. 13, the amplifier has an over sampling (OS) unit 300 at a previous stage of the DPD 200, and this arrows the clock for generating the Tx signal and the PD signal to be 2 times. Therefore, even if the PD signal spectrum after the distortion is compensated is spread in the direction of frequency f, the PD signal spectrums are prevented from overlapping each other, thus suppressing the aliases A1 and A2.

Patent Document 1: Japanese Laid-open Patent Publication No. 07-66687

Patent Document 2: U.S. Patent No. 6298097

Non Patent Document 1: Hsin-Hung Chen, Chih-Hung Lin, Po-Chiun Huang, and Jiunn-Tsair Chen, “Joint Polynomial and Look-Up-Table Predistortion Power Amplifier Linearization,” IEEE Transactions On Circuits And Systems-II: EXPRESS BRIEFS, VOL. 53, NO. 8, AUGUST 2006.

Non Patent Document 2: Y. Akaiwa “Introduction to Digital Mobile Communication,” Wiley, New York (1997).

Non Patent Document 3: Lei Ding et al., “A Robust Digital Baseband Predistorter Constructed Using Memory Polynomials,” IEEE Transaction On Communications, Vol. 52, No 1, Jan. 2004.

Non Patent Document 4:. R. Marsalek, P. Jardin, and G. Baudoin, “From Post-Distortion to Pre-Distortion for Power Amplifiers Linearization, “IEEE Communications Letters, VOL. 7, NO. 7, JULY 2003.

Non Patent Document 5: Yuelin Ma, et al, “An open-loop digital predistorter based on memory polynomial inverses for linearization of RF power amplifier,” International Journal of RF and Microwave Computer-Aided Engineering, September 2011, Volume 21, Issue 5 Pages 457-610.

For the technology, however, there remains a problem that it is difficult to simplify the architecture of the amplifier although the alias of the PD signal can be suppressed. In other words, the related amplifier adapts the architecture of oversampling the main signal (Tx signal) requested for high processing precision along with the PD signal. In the related amplifier, in addition to a path through which the PD signal passes, a path through which the main signal passes provides a dynamic range. Moreover, because the related amplifier processes the main signal at a high speed rate, high performance for a filter for oversampling is sometimes requested. These requests cause the architecture of the amplifier to be complicated and the scale of the hardware to be increased.

### SUMMARY

According to an aspect of the embodiments, an amplifier includes: an increase unit configured to increase a rate of an input signal and samples the input signal; a generator that generates a predistorter signal for compensating for distortion occurring due to amplification of the input signal, from the input signal whose rate is increased by the increase unit; a decrease unit configured to decrease a rate of the predistorter signal generated by the generator to the rate before being increased by the increase unit; an adder that adds the predistorter signal whose rate is decreased by the decrease unit to the input signal before the rate is increased; and an amplification unit configured to amplify the input signal to which the predistorter signal is added by the adder.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates a diagram of an overall architecture of the transmitter;

FIG. 2 illustrates a block diagram of the DPD amplifier according to the present embodiment;

FIG. 3 illustrates a diagram of the spectrum of a signal input to the OS unit of the DPD amplifier;

FIG. 4 illustrates a diagram of the spectrum of a signal output from the OS unit of the DPD amplifier;

FIG. 5 illustrates a diagram of the spectrum of a signal output from the IMDLUT unit of the DPD amplifier;

FIG. 6 illustrates a diagram of the spectrum of a signal output from the LPF of the DPD amplifier;

FIG. 7 illustrates a diagram of the spectrum of a signal output from the DS unit of the DPD amplifier;

FIG. 8 illustrates a diagram of the spectrum of a signal output from the adder of the DPD amplifier;

FIG. 9 illustrates a diagram for explaining an effect in which the dynamic range is decreased by the DPD amplifier;

FIG. 10 illustrates a diagram of how the input signal spectrum is spread by HPA;

FIG. 11 illustrates a diagram of how the input signal is compensated by DPD;

FIG. 12 illustrates a diagram of how aliases arise in PD signal spectrums; and

FIG. 13 illustrates a diagram of how the aliases are suppressed by oversampling.

### DESCRIPTION OF EMBODIMENTS

Preferred embodiments will be explained with reference to accompanying drawings. It is noted that the amplifier, the transmitter, and the amplification method disclosed according to the present application are not limited by the embodiments.

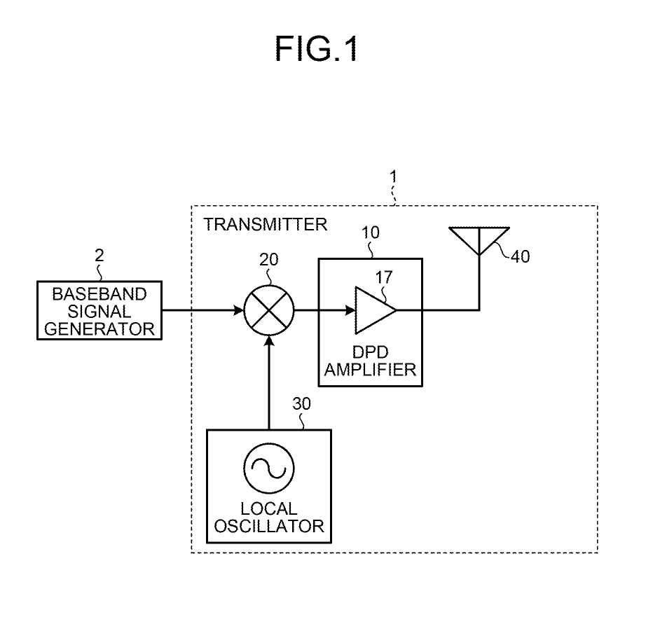

FIG. 1 illustrates a diagram of an overall architecture of the transmitter. As illustrated in FIG. 1, a transmitter 1 according to the present embodiment includes a DPD amplifier 10, a multiplier 20, a local oscillator 30, and an antenna 40. The transmitter 1 is implemented in, for example, a base station. First of all, an entire operation of the transmitter 1 according to the present embodiment will be explained below with reference to FIG. 1. Thereafter, a predistortion process in the DPD amplifier 10 according to the present embodiment will be explained in detail below.

A baseband signal generator 2 generates a baseband signal based on input data such as voice. The baseband signal generator 2 outputs the generated baseband signal to the transmitter 1. The baseband signal generator 2 includes, for example, a digital circuit, a digital signal processor (DSP), and a central processing unit (CPU).

The multiplier 20 receives the baseband signal from the baseband signal generator 2. The multiplier 20 also receives a local oscillation signal from the local oscillator 30. The multiplier 20 multiplies the baseband signal by a carrier frequency of the local oscillation signal to convert the frequency, and generates an RF signal. The multiplier 20 outputs the generated RF signal to the DPD amplifier 10.

The DPD amplifier 10 includes a high power amplifier (HPA) 17. The HPA 17 may be a plurality of units. The DPD amplifier 10 receives the RF signal from the multiplier 20 and amplifies the RF signal using the HPA 17. The DPD amplifier 10 performs oversampling and downsampling on the IMD signal as a predistorter (PD) component (hereinafter, “PD signal”) before the amplification process, and the details thereof will be explained later. The DPD amplifier 10 transmits the amplified signal through the antenna 40.

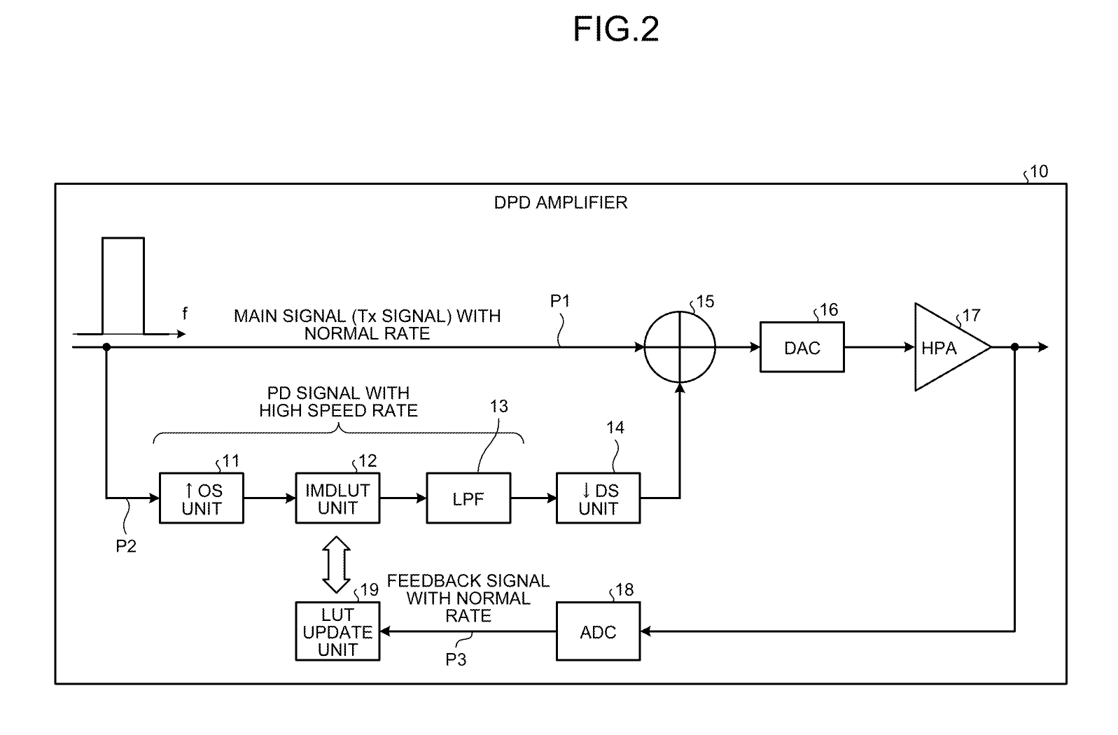

FIG. 2 illustrates a block diagram of the DPD amplifier 10 according to the present embodiment. As illustrated in FIG. 2, the DPD amplifier 10 includes an over sampling (OS) unit 11, an intermodulation distortion look up table (IMDLUT) unit 12, a low pass filter (LPF) 13, a down sampling (DS) unit 14, and an adder 15. The DPD amplifier 10 further includes a digital to analog converter (DAC) 16, the HPA 17, an analog to digital converter (ADC) 18, and a LUT update unit 19. The components are coupled to one another via a data line so that signals and data can be unidirectionally or bidirectionally input and output.

The OS unit 11 oversamples the main signal (Tx signal). That is, the OS unit 11 places the main signal onto a clock which is n times (e.g., n=2) of the main signal, and outputs the signal with a high speed rate to the IMDLUT unit 12 provided at the subsequent stage.

When receiving the n-clock signal, the IMDLUT unit 12 generates a PD signal with a high speed rate from the signal. That is, the IMDLUT unit 12 estimates what sort of intermodulation distortion arises in the HPA 17 by referring to LUT provided for only PD signals, and generates a PD signal having an inverse correlation of the distortion based on the estimation result. Therefore, the IMDLUT unit 12 appropriately compensates for the distortion occurring in the main signal in the HPA 17 at the subsequent stage.

The LPF 13 cuts off a frequency component of the PD signal input from the IMDLUT unit 12 higher than a predetermined frequency, and passes through only a low frequency component as a signal. Thus the LPF 13 reduces the bandwidth (frequency bandwidth) of the PD signal and removes noise in harmonic.

The DS unit 14 down-samples the PD signal input from the LPF 13. That is, the DS unit 14 places the PD signal onto a clock which is 1/n times (e.g., n=2) of the PD signal to be returned to a normal rate, and then outputs the PD signal to the adder 15 at the subsequent stage. Thus the DS unit 14 provides rate matching between the main signal and the PD signal.

The adder 15 adds the PD signal, which passes through an IMD path P2 to the DS unit 14 and is supplied from the DS unit 14, to the main signal (Tx signal) passing through a direct path P1 while maintaining the normal rate.

The DAC 16 converts the digital signal after the addition input from the adder 15 into an analog signal that can be amplified by the HPA 17.

The HPA 17 amplifies the analog signal input from the DAC 16 and generates a transmission signal in which the intermodulation distortion is compensated.

The ADC 18 re-converts the amplified analog signal fed back thereto from the HPA 17 into the digital signal that can be referred to by the IMDLUT unit 12, and outputs the converted signal to the LUT update unit 19 at the normal rate.

The LUT update unit 19 updates the LUT data referred to by the IMDLUT unit 12 based on the feedback signal input from the ADC 18 at the normal rate. The update process does not need to be executed at the speed at which the oversampling is performed, and therefore the OS unit is unnecessary on a feedback path P3.

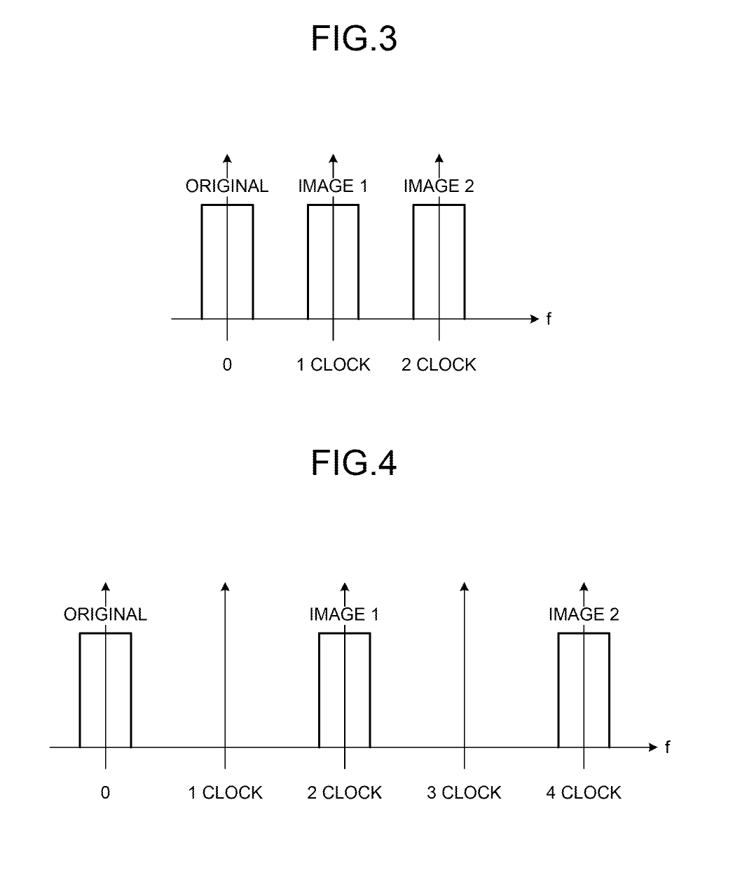

The process from generating the PD signal from the main signal to adding the generated signal to the main signal in the direct path P1 will be explained below with reference to FIG. 3 to FIG. 8.

FIG. 3 illustrates a diagram of the spectrum of a signal input to the OS unit 11 of the DPD amplifier 10. In FIG. 3, frequency f is defined on the x-axis and power P is defined on the y-axis. The center frequency of each of spectrums (original, images 1 and 2) is, for example, 2.1 GHz, and the maximum bandwidth is, for example, 20 MHz to 100 MHz. As illustrated in FIG. 3, because the signal input to the OS unit 11 is the main signal with the normal rate, rectangular spectrums are formed at one clock intervals. In other words, the spectrum of the original image is formed at the time of 0 clock, the spectrum of the image 1 is formed at the time of 1 clock, and the spectrum of the image 2 is formed at the time of 2 clock, the spectrums being formed at equal intervals.

FIG. 4 illustrates a diagram of the spectrum of a signal output from the OS unit 11 of the DPD amplifier 10. As illustrated in FIG. 4, the signal input to the OS unit 11 is over-sampled by the OS unit 11 to become a signal with a high speed rate (e.g., double speed), and is output from the OS unit 11. Because the signal output from the OS unit 11 is the main signal with the high speed rate, rectangular spectrums are formed at two clock intervals. In other words, the spectrum of the original image is formed at the time of 0 clock, the spectrum of the image 1 is formed at the time of 2 clock, and the spectrum of the image 2 is formed at the time of 4 clock, the spectrums being formed at equal intervals.

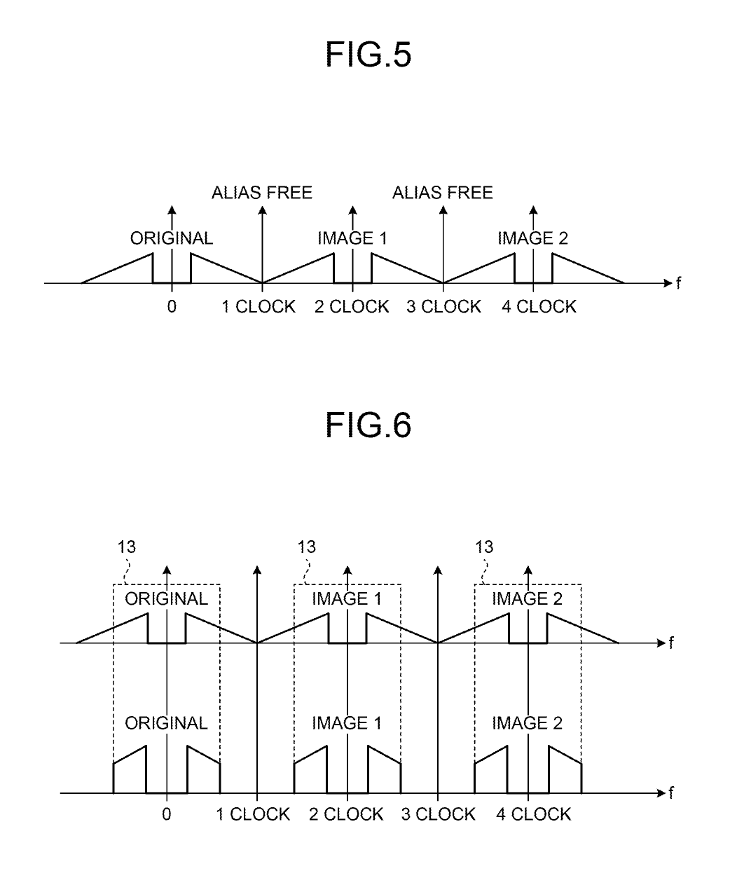

FIG. 5 illustrates a diagram of the spectrum of a signal output from the IMDLUT unit 12 of the DPD amplifier 10. As illustrated in FIG. 5, the IMDLUT unit 12 generates the spectrum of the PD signal, which has an inverse correlation of the intermodulation distortion occurring upon amplification and from which the spectrum of the main signal is removed, according to an instruction of the LUT update unit 19. When the PD signal is generated, because the signal passing through the IMD path P2 is over-sampled, adjacent spectrums never overlap each other even if the IMDLUT unit 12 uses the inverse correlation of the signal. Thus, as illustrated in FIG. 5, no aliasing arises in the IMDLUT unit 12.

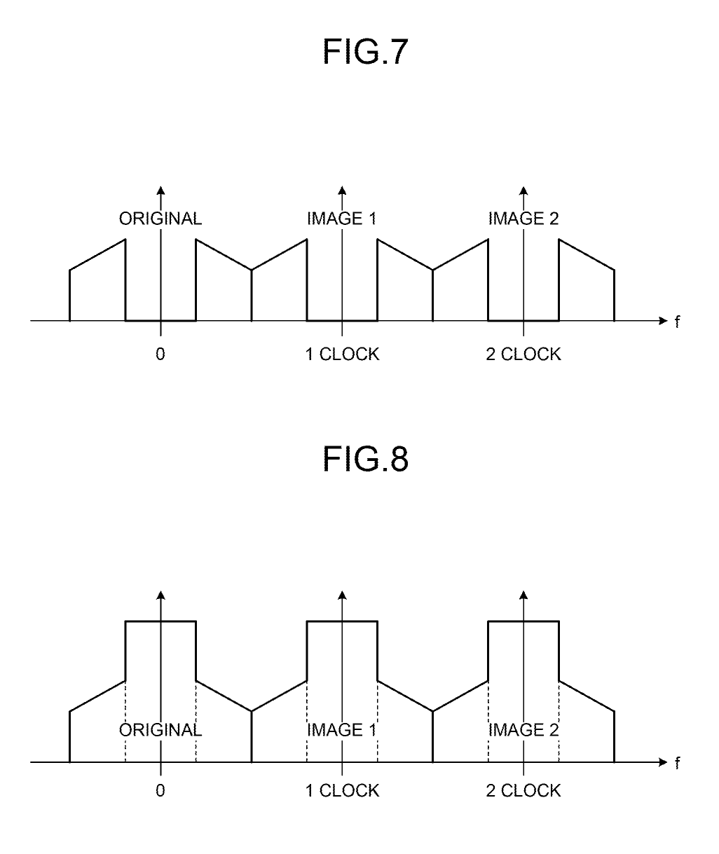

FIG. 6 illustrates a diagram of the spectrum of a signal output from the LPF 13 of the DPD amplifier 10. As illustrated in FIG. 6, each of the spectrums (the original, the images 1 and 2) illustrated in FIG. 5 passes through the LPF 13, and each parts of its both sides are thereby cut off. FIG. 7 illustrates a diagram of the spectrum of a signal output from the DS unit 14 of the DPD amplifier 10. As illustrated in FIG. 7, the DS unit 14 down-samples the PD signal to the rate when it is input to the IMD path P2, i.e., to the rate the same as that of the main signal. At this time point, the both ends of each of the spectrums (the original, the images 1 and 2) of the PD signal are cut off, and therefore even if the downsampling is performed, the spectrums never overlap each other, and an alias-free state is continued.

FIG. 8 illustrates a diagram of the spectrum of a signal output from the adder 15 of the DPD amplifier 10. As illustrated in FIG. 8, the adder 15 adds the main signal (see FIG. 3) passing through the direct path P1 and the PD signal of the spectrum illustrated in FIG. 7 at the normal rate.

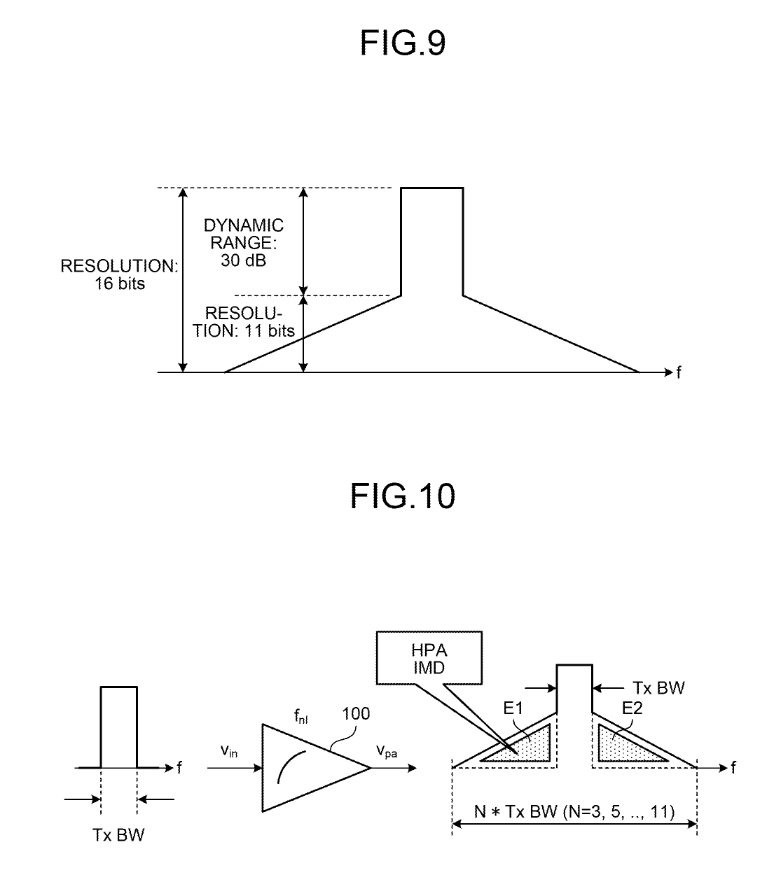

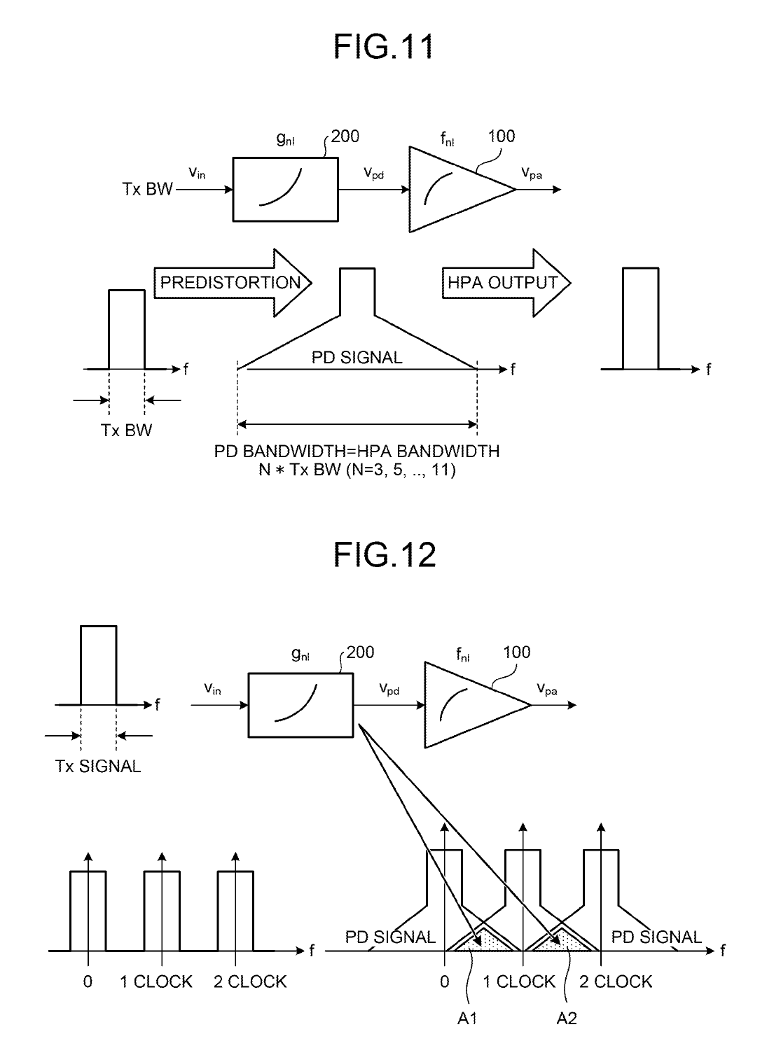

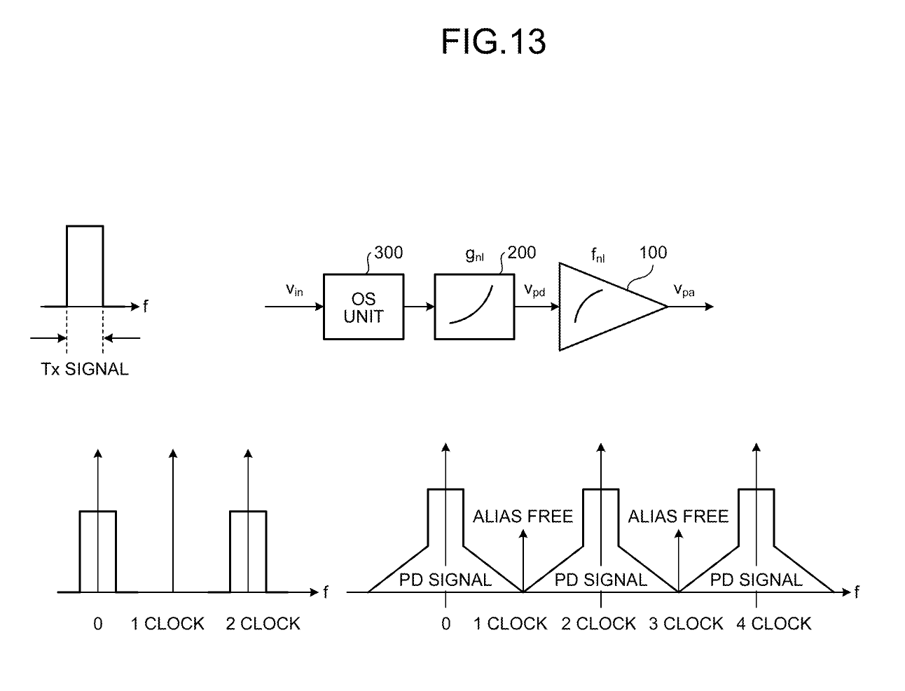

An effect of the predistortion process executed by the DPD amplifier 10 will be explained below with reference to FIG. 9. FIG. 9 illustrates a diagram for explaining an effect in which the dynamic range is decreased by the DPD amplifier 10. The DPD amplifier 10 does not perform oversampling in the direct path P1 and in the feedback path P3 but only in the IMD path P2. Therefore, as illustrated in FIG. 9, the dynamic range decreases to the range corresponding to that of the IMD path P2 (e.g., about 30 dB). In association with this, the requested resolution also decreases to, for example, about 5 bits. Furthermore, because the target to be over-sampled is not all the signals but is limited only to the PD signal, the power consumption along with the oversampling also decreases to, for example, about 30%.

As explained above, the DPD amplifier 10 according to the present embodiment includes the OS unit 11, the IMDLUT unit 12, the DS unit 14, the adder 15, and the HPA 17. The OS unit 11 increases the rate of the input signal (Tx signal) and samples the input signal. The IMDLUT unit 12 generates a predistorter signal (PD signal) for compensating for distortion occurring due to the amplification of the input signal, from the input signal in which the rate is increased by the OS unit 11. The DS unit 14 decreases the rate of the predistorter signal generated by the IMDLUT unit 12 to the rate before it is increased by the OS unit 11. The adder 15 adds the predistorter signal, in which the rate is decreased by the DS unit 14, to the input signal before the rate is increased. The HPA 17 amplifies the input signal to which the predistorter signal is added by the adder 15. The DPD amplifier 10 may further include the LPF 13 that decreases the frequency bandwidth of the predistorter signal generated by the IMDLUT unit 12 and outputs the signal to the DS unit 14. Moreover, the IMDLUT unit 12 may generate the predistorter signal in a second path (IMD path P2) with a higher rate than the predetermined rate while transmitting the input signal before the rate is increased through a first path (direct path P1) with the predetermined rate.

In other words, in the DPD amplifier 10, the OS unit 11 and the DS unit 14 are arranged in IMD path P2 through which the PD signal passes instead of the direct path P1 through which the main signal (Tx signal) passes. Therefore, the DPD amplifier 10 performs oversampling only on a prediction component (PD signal) but does not perform oversampling on the main signal. In other words, only the PD signal is generated at the oversampling rate, in the meantime, the main signal is transmitted at the normal rate. The processing precision as high as that of the main signal is not requested for the PD signal. In addition, as explained above, only the IMD path P2 through which the PD signal passes provides the dynamic range. Moreover, because the DPD amplifier 10 processes the main signal at the normal rate (not at the high speed rate), there is no need to provide the filter for oversampling in the direct path P1. Therefore, the hardware scale of the DPD amplifier 10 is reduced. This enables the DPD amplifier 10 to compensate for the nonlinear distortion of the HPA 17 with a simple architecture.

In the embodiment, the OS unit 11 of the DPD amplifier 10 oversamples the input signal using a clock which is 2 times of the input signal (see FIG. 4). However, the oversampling rate is not necessarily 2 times, and therefore the OS unit 11 can variably set the magnification properly within a range where no aliasing arises between the spectrums after the predistortion. For example, the oversampling rate may be about 1.5 times or 3 times. In association with this, a downsampling rate is not necessarily ½ times, and the DS unit 14 can change the magnification as requested according to the oversampling rate.

In accordance with one aspect of the amplifier disclosed according to the present application, the architecture of the amplifier can be simplified.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An amplifier comprising:
an increase unit configured to increase a rate of an input signal and samples the input signal;
a generator that generates a predistorter signal for compensating for distortion occurring due to amplification of the input signal, from the input signal whose rate is increased by the increase unit;
a decrease unit configured to decrease a rate of the predistorter signal generated by the generator to the rate before being increased by the increase unit;
an adder that adds the predistorter signal whose rate is decreased by the decrease unit to the input signal before the rate is increased; and
an amplification unit configured to amplify the input signal to which the predistorter signal is added by the adder.

2. The amplifier according to claim 1, further including a filter unit configured to reduce a frequency bandwidth of the predistorter signal generated by the generator and outputs the predistorter signal to the decrease unit.

3. The amplifier according to claim 1, wherein the generator generates the predistorter signal in a second path with a higher rate than a predetermined rate while transmitting the input signal before the rate is increased through a first path with the predetermined rate.

4. A transmitter comprising:
an amplifier; and
a transmission unit configured to transmit a signal amplified by the amplifier, wherein
the amplifier includes:
an increase unit configured to increase a rate of an input signal and samples the input signal;
a generator that generates a predistorter signal for compensating for distortion occurring due to amplification of the input signal, from the input signal whose rate is increased by the increase unit;
a decrease unit configured to decrease a rate of the predistorter signal generated by the generator to the rate before being increased by the increase unit;
an adder that adds the predistorter signal whose rate is decreased by the decrease unit to the input signal before the rate is increased; and
an amplification unit configured to amplify the input signal to which the predistorter signal is added by the adder.

5. An amplification method comprising:
increasing a rate of an input signal and sampling the input signal;
generating a predistorter signal for compensating for distortion occurring due to amplification of the input signal, from the input signal whose rate is increased;
decreasing a rate of the generated predistorter signal to the rate before being increased;
adding the predistorter signal whose rate is decreased to the input signal before the rate is increased; and
amplifying the input signal to which the predistorter signal is added.
